(19) United States
(12) Patent Application Publication
(10) Pub. No.: US 2022/0163586 A1
(43) Pub. Date: May 26, 2022

(54) SELF-DIAGNOSING MEASUREMENT SYSTEM AND SELF-DIAGNOSIS METHOD

(71) Applicant: Rohde & Schwarz GmbH & Co. KG, Munich (DE)

(72) Inventors: Yi Jin, Munich (DE); Hong Jin Kim, Munich (DE); Johann Tost, Munich (DE)

(73) Assignee: Rohde & Schwarz GmbH & Co. KG, Munich (DE)

(21) Appl. No.: 17/104,298

(22) Filed: Nov. 25, 2020

(51) Int. Cl. G01R 31/3187; G01R 27/28; G01R 13/02; G06F 11/07

(52) U.S. Cl. CPC G01R 31/3187; G01R 27/28; G06F 11/0745; G06F 11/0769; G01R 13/0218

(57) ABSTRACT

A self-diagnosing measurement system is described. The measurement system includes a first measurement instrument, a device under test, and a diagnosis module. The first measurement instrument is connected with the device under test in a signal transmitting manner. The first measurement instrument includes a testing module. The testing module is configured to automatically conduct a predefined test routine on the device under test. The diagnosis module is configured to automatically conduct a diagnosis routine on the measurement system in order to detect faults in the measurement system. Further, a self-diagnosis method for detecting faults in a measurement system is described.

### FIELD OF THE DISCLOSURE

Embodiments of the present disclosure generally relate to a self-diagnosing measurement system. Embodiments of the present disclosure further relate to a self-diagnosis method for detecting faults in a measurement system.

### BACKGROUND

Compliance test systems for compliance testing of electronic devices under test usually comprise several different hardware components, more precisely measurement instruments, cables for connecting the device under test to the measurement instruments, measurement probes for picking up the signal from the device under test, etc. Moreover, the measurement instruments may comprise software and/or firmware for performing the compliance tests.

If a compliance test fails or results of the compliance test seem to be false, for example if the compliance test cannot properly be executed by the measurement system due to a fault in the measurement system, a user of the measurement system usually has to find the fault by performing several types of diagnosis tests on the measurement system manually.

Finding faults in such compliance test systems is a rather time-consuming task and requires considerable amount of expertise from the user, as each of the hardware and software components may be a possible source of the error.

Accordingly, there is a need for a measurement system that allows for an easier detection of faults within the measurement system.

### SUMMARY

Embodiments of the present disclosure provide a self-diagnosing measurement system. In an embodiment, the measurement system comprises a first measurement instrument, a device under test, and a diagnosis module comprising, for example, one or more diagnosis circuits. The first measurement instrument is connected with the device under test in a signal transmitting manner. The first measurement instrument comprises a testing module comprised of, for example, one or more testing circuits. The testing module is configured to automatically conduct a predefined test routine on the device under test. The diagnosis module is configured to automatically conduct a diagnosis routine on the measurement system in order to detect faults in the measurement system.

In general, the measurement system comprises several different possible error sources. For example, there may be a faulty cable, a faulty connection, a firmware error in the (first) measurement instrument, or a software error in the (first) measurement instrument.

Each of these faults may result in a different error that occur during the test routine. For example, no signal or a wrong signal may be transmitted between two or several components of the measurement system. As a further example, a transmitted signal level may be too low, for example lower than expected, or a signal may have an unwanted offset.

The diagnosis module automatically detects faults in the measurement system by the diagnosis routine, e.g., by predefined diagnosis tests or a predefined sequence of diagnosis tests that are performed on the measurement system.

The diagnosis routine may involve a dedicated diagnosis test for each possible error source. The different diagnosis tests of the diagnosis routine may be performed according to a predefined diagnosis test sequence, wherein the predefined diagnosis test sequence may be preset and/or may be modifiable by a user.

For example, the diagnosis module controls the first measurement instrument to generate a diagnosis test signal and to transmit the diagnosis test signal to the device under test. The diagnosis routine may comprise checking whether the diagnosis test signal arrives at the device under test, whether the signal strength of the diagnosis test signal arriving at the device under test is large enough, whether a response signal from the device under test arrives at the first measurement instrument, and/or whether the signal strength of the response signal is large enough. This way, a faulty cable and/or a faulty connection within the measurement system may be identified.

Thus, the self-diagnosing measurement system according to the present disclosure is configured to verify the functionality of the first measurement instrument, a general functionality of the device under test, a functionality of the communication between the first measurement instrument and the device under test automatically by the diagnosis routine.

The diagnosis module performs the diagnosis routine automatically, such that there is no need for a user to set specific parameters for the diagnosis routine. Thus, the expertise required from a user of the measurement system for running a diagnosis on the measurement system as well as the time needed for performing diagnosis tests on the measurement system are reduced considerably.

According to an aspect of the present disclosure, the diagnosis module is configured to control the first measurement instrument in order to conduct the diagnosis routine. For example, the diagnosis module may control the first measurement instrument to enter a certain operational mode, e.g., a certain measurement mode. Alternatively or additionally, the diagnosis module may control the first measurement instrument to generate a certain diagnosis test signal that is forwarded to the device under test, wherein the diagnosis test signal has predefined properties depending on the exact type of diagnosis test to be performed. A response of the device under test to the diagnosis test signal may be analyzed by the first measurement instrument and/or by the diagnosis module.

According to another aspect of the present disclosure, the first measurement instrument comprises the diagnosis module. In other words, the diagnosis module is integrated into the first measurement instrument, such that the first measurement instrument is configured to perform the diagnosis routine on the measurement system. Accordingly, the first measurement instrument is established as a self-testing measurement instrument that is configured to verify the functionality of its own hardware, software, and/or firmware. Moreover, the first measurement instrument is configured to verify the functionality of other components of the measurement system, such as cables, connectors, further measurement instruments, etc.

In an embodiment of the present disclosure, the measurement system comprises a separately formed computing device comprising one or more computer circuits being connected to the first measurement instrument, wherein the computing device is configured to control the first measurement instrument. The separately formed computing device may comprise corresponding hardware and software that is configured to control the first measurement instrument. In some embodiments, the separately formed computing device may comprise a user interface that can be used by a user of the measurement system in order to control the first measurement instrument, for example in order to initiate a specific test routine, in order to perform specific measurements, and/or in order to start the diagnosis routine.

The separately formed computing device may be established as a computer, such as a PC, a laptop, a smart phone, a tablet, or as any other type of suitable smart device.

In a further embodiment of the present disclosure, the computing device comprises the diagnosis module. Accordingly, the diagnosis routine can be initiated and controlled by the computing device being connected to the first measurement instrument, for example by a user interface of the computing device.

In some embodiments, the diagnosis module may be established as a software module comprising code, executable instructions, etc., that is stored in a memory of the external computing device, wherein the software module may be executed on a processing unit (microprocessor, FPGA, ASIC, DSP, etc.) of the external computing device.

According to another aspect of the present disclosure, the diagnosis module is configured to generate an error report based on the diagnosis routine conducted. In general, the error report comprises information on diagnosis tests conducted within the diagnosis routine and information on whether the individual diagnosis tests have been passed or failed by the measurement system. Additionally, the error report may comprise measurement values that have been obtained during the individual diagnosis tests of the diagnosis routine. Thus, the error report provides an overview of all information that is necessary for debugging the measurement system.

In some embodiments, the error report comprises user guidance information, the user guidance information being associated with at least one of an interpretation of results of the diagnosis routine and a possible way to fix faults in the measurement system. In other words, the user guidance information provides help to a user of the measurement system for interpreting the results and/or gives advice on how to debug the measurement system.

The user guidance information may comprise corresponding text, graphics, pictograms, audio files, video files, etc. For example, the user guidance information may comprise an annotated visual representation of the measurement system with arrows indicating possible error sources within the measurement system, and a description of how to fix these errors.

In a further embodiment of the present disclosure, the predefined test routine is associated with a compliance test. In some embodiments, the predefined test routine may be associated with an Ethernet compliance test. Accordingly, the self-diagnosing measurement system may be established as a self-diagnosing Ethernet compliance test system, for example as a self-diagnosing automotive Ethernet compliance test system.

According to an aspect of the present disclosure, the measurement system comprises connection means, such as one or more connectors, interfaces, etc., the connection means being configured to connect the device under test at least to the first measurement instrument. The connection means may comprise suitable cables, connectors for connecting the cables to the first measurement instrument and/or to the device under test, means for holding (e.g., a holder or a support, such as a shelf, a bench, an arm clamp, test fixture, etc.) the device under test in place, and/or measurement means (e.g., probe, sensor, electrical conductor, etc.) for picking up signals from the device under test.

According to another aspect of the present disclosure, the connection means comprise at least one of a measurement probe and a test fixture. Generally, the measurement probe is configured to pick up a measurement signal from the device under test, and to forward the measurement signal to the first measurement device. The test fixture is configured to hold the device under test in place and/or to fixate the measurement probe at a certain position on the device under test.

The measurement probe may be established as a mass-referenced measurement probe or as a differential measurement probe. In some embodiments, the measurement probe is established as a high-impedance differential probe.

In an embodiment of the present disclosure, the first measurement instrument is established as an oscilloscope. In some embodiments, the oscilloscope is established as a digital oscilloscope with corresponding software. Alternatively, the first measurement instrument may be established as a vector signal analyzer or as a vector network analyzer.

According to a further embodiment of the present disclosure, the measurement system comprises at least one second measurement instrument. Certain types of compliance tests require using two different types of measurement instruments for measuring different aspects of the performance of the device under test at the same time. Accordingly, the diagnosis routine may comprise diagnosis tests for checking the functionality of the second measurement instrument alone, or for checking the functionality of the second measurement instrument in combination with the first measurement instrument and/or in combination with the device under test.

In some embodiments, the second measurement instrument is established as at least one of a vector network analyzer or a signal generator. Of course, the self-diagnosing measurement system may comprise both the vector network analyzer and the signal generator, wherein both the vector network analyzer and the signal generator may be connected to the device under test and/or to the first measurement instrument.

Alternatively, the signal generator may be integrated into the first measurement instrument or into the second measurement instrument.

The device under test may be established as a data bus device. In some embodiments, the device under test is established as an Ethernet device that is configured to communicate with other electronic devices based on an Ethernet standard. For example, the device under test may be established as an automotive Ethernet device, which is configured to communicate with other automotive electronic components based on the Ethernet standard.

According to a further aspect of the present disclosure, the diagnosis routine is associated with at least one, for example with two or several, of the following: a software licensing status, an instrument remote control software, a test report generation software, a test data logging software, a remote service, an instrument communication, a text execution engine, a test performance, and/or an advanced test mode control. The remote service may be associated with a customer service that is performed on the measurement system by an external server. For example, the remote service may relate to at least one of the following: a remote test system analysis, a remote calibration of the first measurement instrument and/or of the second measurement instrument, and/or a remote maintenance of the first measurement instrument and/or of the second measurement instrument.

Embodiments of the present disclosure further provide a self-diagnosis method for detecting faults in a measurement system described above, wherein a diagnosis routine is conducted by the diagnosis module in order to detect faults in the measurement system.

Regarding the advantages and further properties of the self-diagnosis method, reference is made to the explanations given above with respect to the self-diagnosing measurement system, which also hold for the self-diagnosis method and vice versa.

According to an aspect of the present disclosure, the first measurement instrument is controlled by the diagnosis module in order to conduct the diagnosis routine. For example, the diagnosis module may control the first measurement instrument to enter a certain operational mode, for example a certain measurement mode. Alternatively or additionally, the diagnosis module may control the first measurement instrument to generate a certain diagnosis test signal that is forwarded to the device under test, wherein the diagnosis test signal has predefined properties depending on the exact type of diagnosis test to be performed. A response of the device under test to the diagnosis test signal may be analyzed by the first measurement instrument and/or by the diagnosis module.

In an embodiment of the present disclosure, the diagnosis routine is associated with at least one, for example with two or several of a software licensing status, an instrument remote control software, a test report generation software, a test data logging software, a remote service, an instrument communication, a text execution engine, a test performance, and/or an advanced test mode control. For example, a remote service may relate to a remote test system analysis, to a remote calibration of the first measurement instrument and/or of the second measurement instrument, and/or to a remote maintenance of the first measurement instrument and/or of the second measurement instrument.

According to another aspect of the present disclosure, the device under test is established as a data bus device. In some embodiments, the device under test is established as an Ethernet device that is configured to communicate with other electronic devices based on an Ethernet standard. For example, the device under test may be established as an automotive Ethernet device, which is configured to communicate with other automotive electronic components based on the Ethernet standard.

In some embodiments, the diagnosis routine is associated with a data bus device compliance test. Accordingly, the self-diagnosis method according to the present disclosure may be used in order to diagnose a data bus device compliance test system, for example an automotive data bus device compliance test system.

### DESCRIPTION OF THE DRAWINGS

The foregoing aspects and many of the attendant advantages of the claimed subject matter will become more readily appreciated as the same become better understood by reference to the following detailed description, when taken in conjunction with the accompanying drawings, wherein:

FIG. 1 schematically shows a self-diagnosing measurement system according to an embodiment of the present disclosure;

FIG. 2 shows a representative embodiment of a user interface of the self-diagnosing measurement system of FIG. 1;

FIG. 3 shows an exemplary error report; and

FIG. 4 shows a further error report.

### DETAILED DESCRIPTION

The detailed description set forth below in connection with the appended drawings, where like numerals reference like elements, is intended as a description of various embodiments of the disclosed subject matter and is not intended to represent the only embodiments. Each embodiment described in this disclosure is provided merely as an example or illustration and should not be construed as preferred or advantageous over other embodiments. The illustrative examples provided herein are not intended to be exhaustive or to limit the claimed subject matter to the precise forms disclosed.

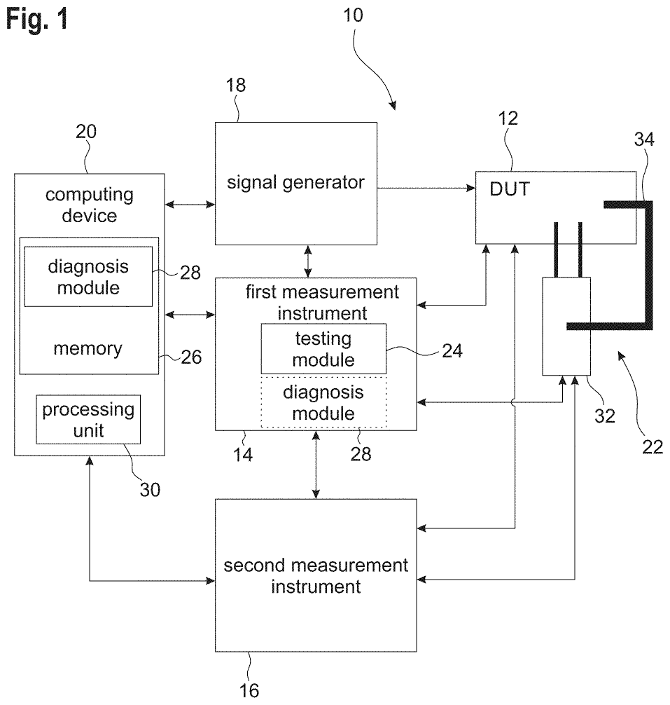

FIG. 1 schematically shows a self-diagnosing measurement system 10. The self-diagnosing measurement system 10 comprises a device under test 12, a first measurement instrument 14, a second measurement instrument 16, a signal generator 18, a computing device 20, and connection means 22, such as a connector.

The device under test 12 is established as, for example, a data bus device. In some embodiments, the device under test 12 is established as an Ethernet device that is configured to communicate with other electronic devices based on an Ethernet standard, e.g. based on Ethernet 10G, Ethernet 2.5/5G, 10BASE-T1, 100BASE-T1, and/or 1000BASE-T1. For example, the device under test 12 may be established as an automotive Ethernet device, which is configured to communicate with other automotive electronic components based on any of the Ethernet standards described above.

The first measurement instrument 14 is established as, for example, an oscilloscope, for example as a digital oscilloscope. The first measurement instrument 14 comprises a testing module 24, comprised for example of one or more testing circuits, that is configured to automatically conduct a predefined test routine on the device under test 12.

In some embodiments, the term “module” refers to a combination of hardware (e.g. a processor such as an integrated circuit or other circuitry) and software (e.g. machine- or processor-executable instructions, commands, or code such as firmware, programming, or object code). Furthermore, a combination of hardware and software may include hardware only (i.e. a hardware element with no software elements), software hosted at hardware (e.g. software that is stored at a memory and executed or interpreted at a processor), or hardware with the software hosted thereon. In some embodiments, the hardware may, inter alia, comprise a central processing unit (CPU), a graphics processing unit (GPU), a field programmable gate array (FPGA), a digital signal processor (DSP), an application specific integrated circuit (ASIC), or other types of electronic circuitry.

The second measurement instrument 16 is established as, for example, a vector network analyzer. Alternatively, the second measurement instrument 16 may be established as a vector signal analyzer, an oscilloscope, or as any other type of measurement instrument that is needed for performing particular (compliance) tests on the device under test 12.

The signal generator 18 is configured to generate a predefined signal generator signal. For example, the signal generator 18 may be established as an arbitrary signal generator. It is noted that the signal generator 18 may also be integrated into the first measurement instrument 14 and/or into the second measurement instrument 16.

In some embodiments, the computing device 20 is established separately from the first measurement instrument 14 and from the second measurement instrument 16. The computing device 20 may be established as a PC, a laptop, a smart phone, a tablet, or as any other type of suitable smart device. In these or other embodiments, the computing device 20 includes one or more processor circuits, etc.

In some embodiments, the computing device 20 comprises a memory 26, a diagnosis module 28, and a processing unit 30. The diagnosis module 28 is established, for example, as a software module that is stored in the memory 26 of the external computing device 20, and that can be executed on the processing unit 30. The processing unit 30 may comprise a CPU, a GPU, an FPGA, an ASIC, a DSP, and/or other types of electronic processing circuitry. Alternatively, the diagnosis module 28, or portions thereof, may be implemented in hardware circuits (e.g., implementations in analog circuitry, implementations in digital circuitry, and the like, and combinations thereof).

As is indicated by the dashed lines in FIG. 1, the diagnosis module 28 may alternatively or additionally be implemented in the first measurement instrument 14.

In some embodiments, the connection means 22 comprises a measurement probe 32 and a test fixture 34. In general, the measurement probe 32 is configured to pick up a measurement signal from the device under test 12 and to forward the measurement signal to the first measurement instrument 14 and/or to the second measurement instrument 16. In some embodiments, the measurement probe 32 is established as a high-impedance differential probe.

The test fixture 34 is configured to hold the device under test 12 in place and/or to fixate the measurement probe 32 with respect to the device under test 12, e.g. in a particular measurement position. For example, the test fixture 34 may comprise a rack with one or several holders, to which the device under test 12 and/or the measurement probe 32 can be attached.

The computing device 20 is connected to each of the first measurement instrument 14, the second measurement instrument 16, and the signal generator 18 in a signal transmitting manner. In general, the term “connected in a signal transmitting manner” is understood to denote a cable-based or wireless connection that is configured to transmit signals between the respective devices or components.

Without restriction of generality, the term “connected in a signal transmitting manner” is understood to denote a cable-based connection in the following. Each of the first measurement instrument 14, the second measurement instrument 16, and the signal generator 18 is connected to the device under test 12 in a signal transmitting manner Moreover, the measurement probe 32 is connected to the first measurement instrument 14, and to the second measurement instrument 16 in a signal transmitting manner Optionally, the first measurement instrument 14, the second measurement instrument 16, and the signal generator 18 may be mutually connected in a signal transmitting manner.

In general, the self-diagnosing measurement system 10 is configured to conduct compliance tests on the device under test 12, for example Ethernet compliance tests. More precisely, the testing module 24 is configured to automatically conduct the compliance tests on the device under test 12.

For this purpose, the testing module 24 may generate a corresponding test signal that is forwarded to the device under test 12. Alternatively or additionally, the testing module 24 may control the signal generator 18 to generate the test signal.

In some embodiments, the computing device 20 may be used to control the first measurement instrument 14, the second measurement instrument 16 and/or the signal generator 18 in order to conduct the compliance tests.

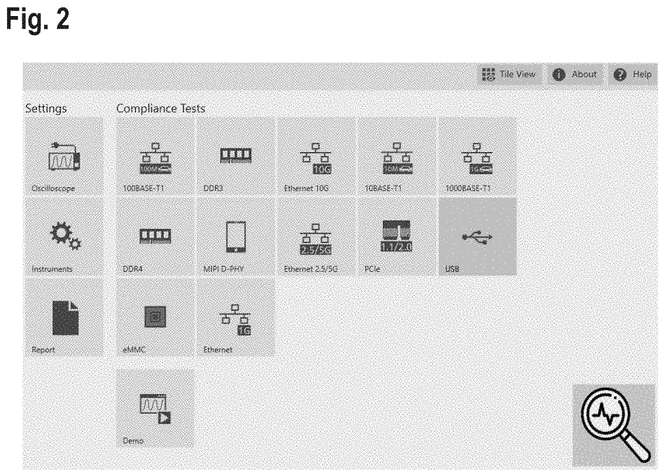

As shown in FIG. 2, the computing device 20 and/or the first measurement instrument 14 may comprise a user interface that can be used by a user of the measurement system in order to control the first measurement instrument 14, for example in order to initiate a specific compliance test routine or in order to perform specific measurements.

A response of the device under test 12 to the test signal is picked up by the measurement probe 32 and is forwarded to the first measurement instrument 14 and/or to the second measurement instrument 16. The first measurement instrument 14 and/or the second measurement instrument 16 then analyzes the response signal of the device under test 12 in order to determine whether the device under test 12 has failed or passed the compliance test.

The self-diagnosing measurement system 10 described above comprises several different possible error sources. For example, there may be a faulty cable connecting two of the components of the self-diagnosing measurement system 10, a faulty connection to one of the components of the self-diagnosing measurement system 10, a firmware error in any of the measurement instruments 14, 16 or in the signal generator 18, or a software error in any of the measurement instruments 14, 16 or in the signal generator 18.

Each of these faults may result in a different error during the compliance tests described above. For example, no signal or a wrong signal may be transmitted between two or several components of the self-diagnosing measurement system. As a further example, a transmitted signal level may be too low, or a signal may have an unwanted offset.

The self-diagnosing measurement system 10 is configured to automatically detect or rather identify such faults within the self-diagnosing measurement system 10 by a self-diagnosis method that is described in more detail in the following.

The diagnosis module 28 automatically conducts a diagnosis routine on the measurement system 10. In some embodiments, the diagnosis routine comprises a sequence of predefined diagnosis tests that are performed on the measurement system 10 in a predefined order. Each diagnosis test is associated with at least one, for example with two or several of a software licensing status, an instrument remote control software, a test report generation software, a test data logging software, a remote service, an instrument communication, a text execution engine, a test performance, and/or an advanced test mode control.

The remote service may be associated with a customer service that is performed on the measurement system 10 by an external server. For example, the remote service may relate to a remote test system analysis. As a further example, the remote service may relate to a remote calibration of the first measurement instrument 14, of the second measurement instrument 16, and/or of the signal generator 18. As another example, the remote service may relate to a remote maintenance of the first measurement instrument 14, of the second measurement instrument 16, of the signal generator 18, or of the computing device 20.

The diagnosis module 28 may control the first measurement instrument 14, the second measurement instrument 16, and/or the signal generator 18 in order to conduct the diagnosis routine. Thus, the diagnosis module 28 may control the first measurement instrument 14, the second measurement instrument 16, and/or the signal generator 18 to enter a certain operational mode, e.g. a certain measurement mode.

Alternatively or additionally, the diagnosis module 28 may control the first measurement instrument 14, the second measurement instrument 16, and/or the signal generator 18 to generate a certain diagnosis test signal that is forwarded to the device under test 12, wherein the diagnosis test signal has predefined properties depending on the exact type of diagnosis test to be conducted.

A response signal of the device under test 12 to the diagnosis test signal is picked up by the measurement probe 32 and is forwarded to the first measurement instrument 14 and/or to the second measurement instrument 16. The response signal of the device under test 12 to the diagnosis test signal may also be forwarded to the computing device 20.

The response signal of the device under test 12 is analyzed by the first measurement instrument 14, the second measurement instrument 16 and/or the diagnosis module 28. The analysis results obtained by the first measurement instrument 14 and/or the second measurement instrument 16 may also be forwarded to the diagnosis module 28.

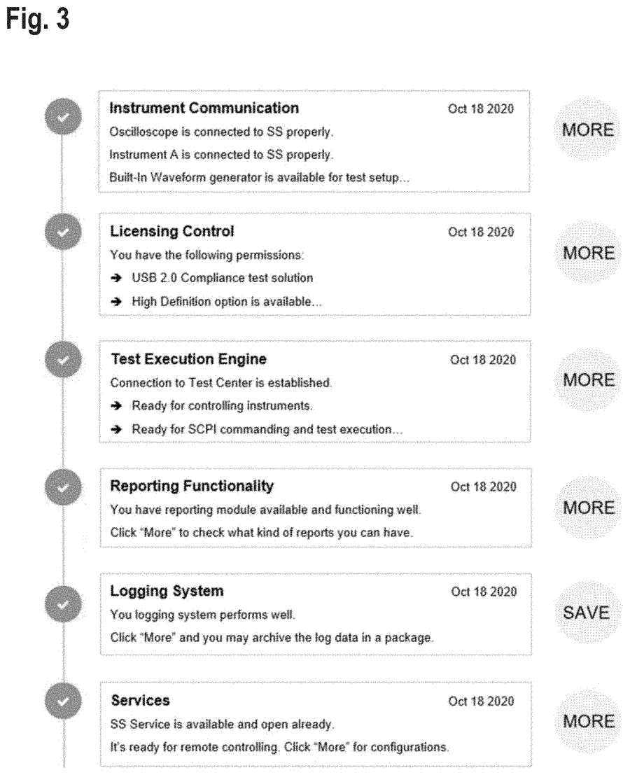

The diagnosis module 28 generates an error report based on the results of the individual diagnosis tests. An example for such an error report is shown in FIG. 3.

The error report comprises information on the individual diagnosis tests conducted within the diagnosis routine, for example on the individual components of the measurement system 10 targeted by the respective diagnosis test. Moreover, the error report comprises information on whether the individual tests have been passed or failed by the measurement system 10. Additionally, the error report may comprise measurement values that have been obtained during the individual diagnosis tests of the diagnosis routine. Thus, the error report provides an overview of all information that is necessary for debugging the measurement system 10.

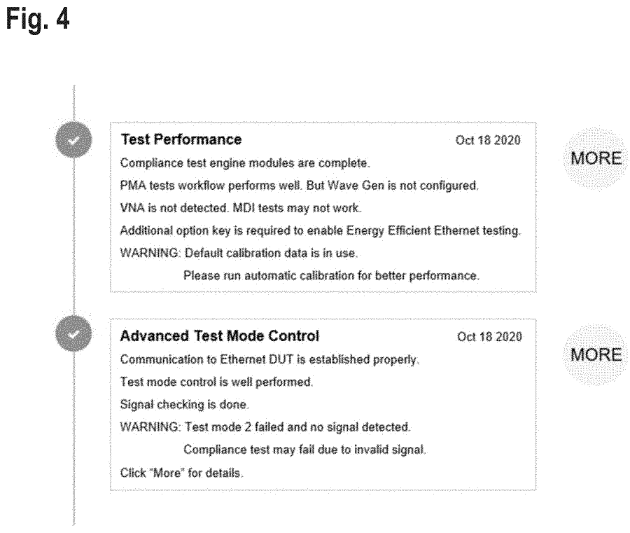

As is illustrated in FIG. 4, the error report may further comprise user guidance information. The user guidance information is associated with an interpretation of the results of the diagnosis routine and a possible way to fix faults in the measurement system 10, if at least one such fault has been encountered.

For example, the upper box in FIG. 4, which is labeled “Test Performance”, comprises a warning for the user that default calibration data (e.g. for the second measurement instrument 16 being established as a vector signal analyzer) is in use, which may impair the test performance. The user is instructed to run an automatic calibration in order to enhance the test performance.

The user guidance information may comprise text, graphics, pictograms, audio files, video files, etc. For example, the user guidance information may comprise an annotated visual representation of the measurement system 10 with arrows indicating possible error sources within the measurement system 10, and a description of how to fix these errors. Such user guidance information may be suitable rendered on a display associated with the test system,

Summarizing, the self-diagnosing measurement system 10 described above is configured to verify the functionality of all of its components automatically by the diagnosis routine that is conducted by the diagnosis module 28. The diagnosis module 28 performs the diagnosis routine automatically, such that there is no need for a user to set specific parameters for the diagnosis routine. Thus, the expertise required from user of the measurement system 10 for running a diagnosis on the measurement system 10 as well as the time needed for performing diagnosis tests on the measurement system 10 are reduced considerably.

Certain embodiments disclosed herein utilize circuitry (e.g., one or more circuits) in order to implement standards, protocols, methodologies or technologies disclosed herein, operably couple two or more components, generate information, process information, analyze information, generate signals, encode/decode signals, convert signals, transmit and/or receive signals, control other devices, etc. Circuitry of any type can be used. It will be appreciated that the term “information” can be use synonymously with the term “signals” in this paragraph. It will be further appreciated that the terms “circuitry,” “circuit,” “one or more circuits,” etc., can be used synonymously herein.

In an embodiment, circuitry includes, among other things, one or more computing devices such as a processor (e.g., a microprocessor), a central processing unit (CPU), a digital signal processor (DSP), an application-specific integrated circuit (ASIC), a field-programmable gate array (FPGA), a system on a chip (SoC), or the like, or any combinations thereof, and can include discrete digital or analog circuit elements or electronics, or combinations thereof. In an embodiment, circuitry includes hardware circuit implementations (e.g., implementations in analog circuitry, implementations in digital circuitry, and the like, and combinations thereof).

In an embodiment, circuitry includes combinations of circuits and computer program products having software or firmware instructions stored on one or more computer readable memories that work together to cause a device to perform one or more protocols, methodologies or technologies described herein. In an embodiment, circuitry includes circuits, such as, for example, microprocessors or portions of microprocessor, that require software, firmware, and the like for operation. In an embodiment, circuitry includes one or more processors or portions thereof and accompanying software, firmware, hardware, and the like.

In some examples, the functionality described herein can be implemented by special purpose hardware-based computer systems or circuits, etc., or combinations of special purpose hardware and computer instructions.

Of course, in some embodiments, two or more of these components, or parts thereof, can be integrated or share hardware and/or software, circuitry, etc. In some embodiments, these components, or parts thereof, may be grouped in a single location or distributed over a wide area. In circumstances were the components are distributed, the components are accessible to each other via communication links.

The present application may reference quantities and numbers. Unless specifically stated, such quantities and numbers are not to be considered restrictive, but exemplary of the possible quantities or numbers associated with the present application. Also in this regard, the present application may use the term “plurality” to reference a quantity or number. In this regard, the term “plurality” is meant to be any number that is more than one, for example, two, three, four, five, etc. The terms “about”, “approximately”, “near” etc., mean plus or minus 5% of the stated value.

Certain embodiments disclosed herein utilize circuitry (e.g., one or more circuits) in order to implement protocols, methodologies or technologies disclosed herein, operably couple two or more components, generate information, process information, analyze information, generate signals, encode/decode signals, convert signals, transmit and/or receive signals, control other devices, etc. Circuitry of any type can be used.

In an embodiment, circuitry includes, among other things, one or more computing devices such as a processor (e.g., a microprocessor), a central processing unit (CPU), a digital signal processor (DSP), an application-specific integrated circuit (ASIC), a field-programmable gate array (FPGA), a system on a chip (SoC), or the like, or any combinations thereof, and can include discrete digital or analog circuit elements or electronics, or combinations thereof. In an embodiment, circuitry includes hardware circuit implementations (e.g., implementations in analog circuitry, implementations in digital circuitry, and the like, and combinations thereof).

In an embodiment, circuitry includes combinations of circuits and computer program products having software or firmware instructions stored on one or more computer readable memories that work together to cause a device to perform one or more protocols, methodologies or technologies described herein. In an embodiment, circuitry includes circuits, such as, for example, microprocessors or portions of microprocessor, that require software, firmware, and the like for operation. In an embodiment, circuitry includes an implementation comprising one or more processors or portions thereof and accompanying software, firmware, hardware, and the like.

The present application may reference quantities and numbers. Unless specifically stated, such quantities and numbers are not to be considered restrictive, but exemplary of the possible quantities or numbers associated with the present application. Also in this regard, the present application may use the term “plurality” to reference a quantity or number. In this regard, the term “plurality” is meant to be any number that is more than one, for example, two, three, four, five, etc. The terms “about,” “approximately,” “near,” etc., mean plus or minus 5% of the stated value. For the purposes of the present disclosure, the phrase “at least one of A and B” is equivalent to “A and/or B” or vice versa, namely “A” alone, “B” alone or “A and B.”. Similarly, the phrase “at least one of A, B, and C,” for example, means (A), (B), (C), (A and B), (A and C), (B and C), or (A, B, and C), including all further possible permutations when greater than three elements are listed.

The principles, representative embodiments, and modes of operation of the present disclosure have been described in the foregoing description. However, aspects of the present disclosure which are intended to be protected are not to be construed as limited to the particular embodiments disclosed. Further, the embodiments described herein are to be regarded as illustrative rather than restrictive. It will be appreciated that variations and changes may be made by others, and equivalents employed, without departing from the spirit of the present disclosure. Accordingly, it is expressly intended that all such variations, changes, and equivalents fall within the spirit and scope of the present disclosure, as claimed.

The embodiments of the invention in which an exclusive property or privilege is claimed are defined as follows:

1. A self-diagnosing measurement system, the measurement system comprising a first measurement instrument, a device under test, and a diagnosis circuit,
the first measurement instrument being connected with the device under test in a signal transmitting manner,
the first measurement instrument comprising a testing circuit,
the testing circuit being configured to automatically conduct a predefined test routine on the device under test, and
the diagnosis circuit being configured to automatically conduct a diagnosis routine on the measurement system in order to detect faults in the measurement system.

2. The measurement system of claim 1, wherein the diagnosis circuit is configured to control the first measurement instrument in order to conduct the diagnosis routine.

3. The measurement system of claim 1, wherein the first measurement instrument comprises the diagnosis circuit.

4. The measurement system of claim 1, wherein the measurement system comprises a separately formed computing device being connected to the first measurement instrument, wherein the computing device is configured to control the first measurement instrument.

5. The measurement system of claim 4, wherein the computing device comprises the diagnosis circuit.

6. The measurement system of claim 1, wherein the diagnosis circuit is configured to generate an error report based on the diagnosis routine conducted.

7. The measurement system of claim 6, wherein the error report comprises user guidance information, the user guidance information being associated with at least one of an interpretation of results of the diagnosis routine and a possible way to fix faults in the measurement system.

8. The measurement system of claim 1, wherein the predefined test routine is associated with a compliance test.

9. The measurement system of claim 1, wherein the measurement system comprises connection means, the connection means being configured to connect the device under test at least to the first measurement instrument.

10. The measurement system of claim 9, wherein the connection means comprise at least one of a measurement probe and a test fixture.

11. The measurement system of claim 1, wherein the first measurement instrument is established as an oscilloscope.

12. The measurement system of claim 1, wherein the measurement system comprises at least one second measurement instrument.

13. The measurement system of claim 12, wherein the second measurement instrument is established as at least one of a vector network analyzer and a signal generator.

14. The measurement system of claim 1, wherein the device under test is established as a data bus device.

15. The measurement system of claim 1, wherein the diagnosis routine is associated with at least one of a software licensing status, an instrument remote control software, a test report generation software, a test data logging software, a remote service, an instrument communication, a text execution engine, a test performance, and an advanced test mode control.

16. A self-diagnosis method for detecting faults in a measurement system according to claim 1, wherein a diagnosis routine is conducted by the diagnosis circuit in order to detect faults in the measurement system.

17. The self-diagnosis method of claim 16, wherein the first measurement instrument is controlled by the diagnosis circuit in order to conduct the diagnosis routine.

18. The self-diagnosis method of claim 16, wherein the diagnosis routine is associated with at least one of a software licensing status, an instrument remote control software, a test report generation software, a test data logging software, a remote service, an instrument communication, a text execution engine, a test performance, and an advanced test mode control.

19. The self-diagnosis method of claim 16, wherein the device under test is established as a data bus device.

20. The self-diagnosis method of claim 19, wherein the diagnosis routine is associated with a data bus device compliance test.
